(19) United States
(12) Patent Application Publication
(10) Pub. No.: US 2011/0260149 A1
(43) Pub. Date: Oct. 27, 2011

(54) N-Phenyl carbazole-based host material for light-emitting diodes

(75) Inventors: Roland Martin, St-Stevens-Woluwe (BE); Veronique Mathieu, Wavre (BE); Victor Sorokin, Cincinnati, OH (US); Praveen Bachawala, Cincinnati, OH (US); Wieslaw Adam Mazur, Mason, OH (US)

(73) Assignee: SOLVAY SA, Brussels (BE)

(21) Appl. No.: 13/124,251

(22) PCT Filed: Oct. 15, 2009
(86) PCT No.: PCT/EP2009/063517

§ 371 Date: Jul. 1, 2011

Related U.S. Application Data
(60) Provisional application No. 61/105,841, filed on Oct. 16, 2008.

(30) Foreign Application Priority Data
Nov. 27, 2008 (EP) 08170152.6

(51) Int. Cl. H01L 51/54; C07F 7/10

(52) U.S. Cl. 257/40; 548/406; 257/E51.024

(57) ABSTRACT

The present invention relates to a host material comprising a compound having a carbazole moiety which is suitable for blue-emitting OLEDs. Surprisingly, it has been found that when appropriate substituents are present in the carbazole structure, the solubility of the compounds can be improved without any adverse effect on the OLED performance. The present invention further relates to the use of the host materials and to an organic light emitting device comprising the host material.

### REFERENCE TO RELATED APPLICATIONS

This application claims priority to U.S. provisional application 61/105,841 filed on Oct. 16, 2008, and to European patent application 08170152.6 filed on Nov. 27, 2008, both incorporated herein by reference.

### TECHNICAL FIELD

The present invention relates to a host material for light-emitting diodes, to the use of such host material, and to a light-emitting device capable of converting electrical energy into light.

### BACKGROUND

Recently, various display devices have been under active study and development, particularly those based on electroluminescence (EL) from organic materials.

Many organic materials exhibit fluorescence (i.e., luminescence from a symmetry-allowed process) from singlet excitons. Since this process occurs between states of equal symmetry, it may be very efficient. On the contrary, if the symmetry of an exciton is different from that of the ground state, then the radioactive relaxation of the exciton is disallowed and luminescence will be slow and inefficient. Because the ground state is usually anti-symmetric, the decay from a triplet breaks the symmetry. The process is thus disallowed and the efficiency of EL is very low. Therefore, the energy contained in the triplet state is mostly wasted.

The luminescence from a symmetry-disallowed process is known as phosphorescence. Characteristically, phosphorescence may persist up to several seconds after excitation due to the low probability of the transition, in contrast to fluorescence which shows rapid decay. The use of phosphorescent materials has been a major breakthrough in boosting electroluminescence efficiency because they allow for the simultaneous harvesting of both singlet and triplet excitons. Selecting a suitable host material for the phosphorophore dopants remains one of the critical issues in phosphorescence-based OLEDs. The host material is important because efficient exothermic energy transfer from the host material to the dopant phosphorophore depends on whether the triplet-state energy of the host is greater than that of the dopant.

Well known host materials for guest-host systems include hole-transporting 4,4′-N,N′-dicarbazol-biphenyl (CBP) and electron-transporting aluminum 8-hydroxyquinoline (AlQ3), which have both been used in OLEDs. However, the known host materials are not suitable for all phosphorescent guests. For example, the host compound for phosphorescent emitters must fulfil an important condition that the triplet energy of the host shall be higher than that of the phosphorescent emitter. In order to provide efficient phosphorescence from the phosphorescent emitter, the lowest excited triplet state of the host has to be higher in energy than the lowest emitting state of the phosphorescent emitter. Since emission from the phosphorescent emitter is desired, the lowest excited state has to be from the phosphorescent emitter, not the host compound. As such, there continues to be a need in the art for suitable host materials for guests which have short emission wavelengths in the light spectrum, e.g., in the blue region of the spectrum.

Several host materials for better phosphorescent emission have been reported. Due to their charge conducting ability, photophysical and redox properties, sufficiently large triplet energies and carrier-transport properties, carbazole-based compounds have been actively studied.

For example, U.S. Patent Application Publication No. US 2003/205696 assigned to Canon KK discloses guest-host emissive systems suitable for use with organic light emitting devices in which the host material comprises a compound having a carbazole core with an electron-donating species bonded to nitrogen, aromatic amine groups or carbazole groups bonded to one or more of the carbon atoms, a large band gap potential, and high-energy triplet excited states. Such materials permit short-wavelength phosphorescent emission by an associated guest material, and the combination of said materials with emissive phosphorescent organometallic compounds such as platinum complexes is useful in the fabrication of organic light emitting devices.

Japan Patent Application Publication No JP 2004/311412 assigned to Konica Minolta Holdings discloses N-phenyl carbazole compounds used as mixed-host material for phosphorescent dopants in an emissive layer. U.S. Patent Application Publication No. US 2007/173657 assigned to Academia Sinica discloses tetraphenylsilane-carbazole compounds for use as host material for dopants, which are prepared by mixing a selected tetraphenylsilane with carbazole in the existence of additives and reacting them under heated conditions, or by mixing a selected carbazole with butyl metallic and reacting them under a relatively lower temperature. Further, U.S. Patent Application Publication Nos. US 2007/262703 and US 2007/262704, both of which were assigned to Tsai Ming-Han et al. disclose 9-(4-tert-butylphenyl)-3,6-bis(triphenylsilyl)-9H-carbazole as the host material for an emissive layer.

Further, Wu et al., “The Quest for High-Performance Host Materials for Electrophosphorescent Blue Dopants,” Adv. Fund. Mater., 17: 1887-1895 (2007) discloses 3,5-di(N-carbazolyl)tetraphenylsilane (SimCP) and N,N′-dicarbazolyl-3,5-benzene (mCP) as host materials for phosphorescent blue dopants, while Thoms et al., “Improved host material design for phosphorescent guest-host systems,” Thin Sold Films 436: 264-268 (2003) discloses a series of carbazole-based compounds as host materials in an iridium phosphor-based guest-host organic light emitting diode and the results of semi-empirical calculations.

However, none of the above-disclosed materials meet all the requirements necessary for OLED application, e.g., suitable energy level, charge transport ability, processibility from a solution with uniform film formation, ability to form an amorphous phase, ability for good dopant dispersion, morphological stability (high Tg), thermal and electrochemical stabilities under operational conditions of the device. Therefore, there has been a need to develop new host materials which are capable of satisfying all of the requirements indicated above.

### BRIEF DESCRIPTION OF DRAWINGS

FIG. 1 shows a cross-sectional view of a display device containing the organic light emitting device of the present invention.

FIG. 2 shows the ¹H NMR spectra of product 2 of Scheme 1.

FIGS. 3 and 4 show the ¹H NMR and ¹³C NMR spectra of product 3 of Scheme 1.

FIGS. 5 and 6 show the ¹H NMR and ¹³C NMR spectra of product 4 of Scheme 1.

FIGS. 7 and 8 show the ¹H NMR and ¹³C NMR spectra of product 5 of Scheme 1, compound VI.

### DISCLOSURE OF THE INVENTION

One aspect of the present invention relates to a host material comprising a carbazole-based compound as described below.

Another aspect of the present invention relates to the use of the host material for the emissive layer and to an organic light emitting device comprising the host material.

The present invention provides a host material which comprises the compound of Formula I:

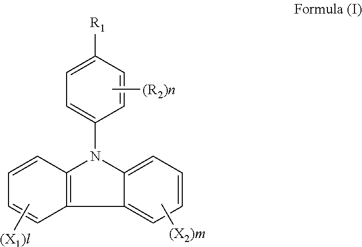

where:
R₁ is selected from the group consisting of:
fluorinated alkyl
trityl
halogen;
nitro;
cyano;
—COOR₃;
—SiR₄R₅R₆; and
alkoxy or dialkylamino group having from 1 to 20 carbon atoms where one or more nonadjacent —CH₂— groups may be replaced by —O—, —S—, —NR₇—, —CO—, —CONR₈— or —COO— and where at least one hydrogen atom may be replaced by halogen;
   R₂, X₁ and X₂ are non-conjugate substituents, the same or different at each occurrence and selected from the group consisting of:
trityl
halogen;
nitro;
cyano;
—COOR₃;
—SiR₄R₅R₆; and
straight-chain or branched or cyclic alkyl or alkoxy or dialkylamino group having from 1 to 20 carbon atoms where one or more nonadjacent —CH₂— groups may be replaced by —O—, —S—, —NR₂—, —CO—, —CONR₇ or —COO— and where at least one hydrogen atom may be replaced by halogen; wherein R₃, R₄, R₅, R₆, R₇, and R₈, are the same or different at each occurrence and independently selected from the group consisting of —H, halogen, nitro, cyano, straight or branched C₁₋₂₀-alkyl, C₃₋₂₀-cyclic alkyl, straight or branched C₁₋₂₀-alkoxy, C₁₋₂₀-dialkylamino, C₄₋₁₄-aryl, C₄₋₁₄-aryloxy, and C₄₋₁₄-heteroaryl, which may be substituted by one or more non aromatic radicals, where a plurality of R₁, R₂, R₄, R₅, R₆, X₁ and X₂ may in turn together form a mono- or polycyclic ring, optionally aromatic; and
   l, m, and n are the same or different at each occurrence and represent an integer from 0 to 4.

In some embodiments of the present invention, R₁ is fluorinated alkyl, halogen or —SiR₄R₅R₆ and each of R₄, R₅ and R₆ is an alkyl group. The applicant has found that these embodiments lead to better compound stability. In a preferred embodiment, R₁ is trialkylsilyl or Si(isopropyl)₃.

In some embodiments of the present invention, each of X₁ and X₂ is a triarylsilyl group or X₁=X₂=—Si(Ph)₃ or

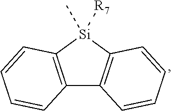

where R₇ is phenyl, isopropyl or methyl.

Surprisingly, it has been found that, when an appropriate substituent such as a trialkylsilyl or triarylsilyl group is introduced to the carbazole structure of the compound of the present invention, its solubility and processibility can be improved without any adverse effects on the other properties, such as color, efficiency, etc.

Specifically, some embodiments of the present invention include the following compounds represented by Formulae II to VIII:

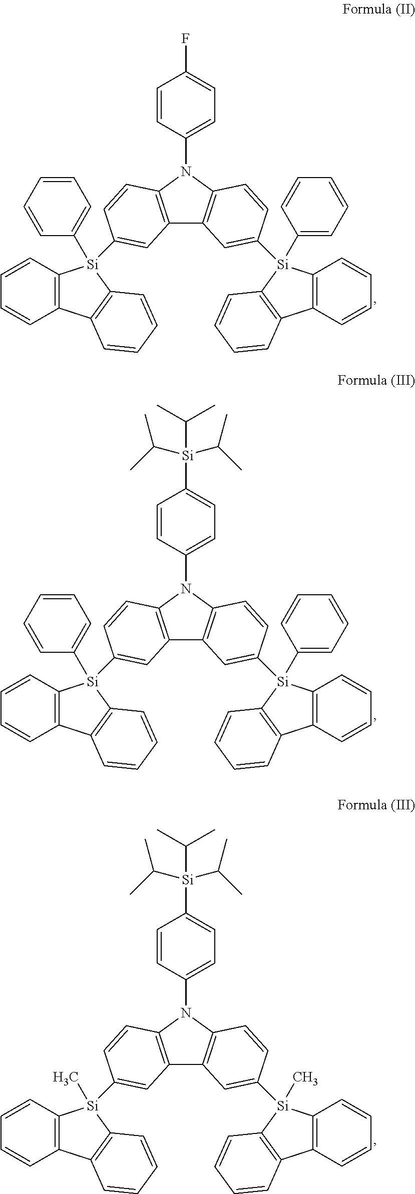

Formula (IV) (where the methyl groups may be replaced by isopropyl groups),

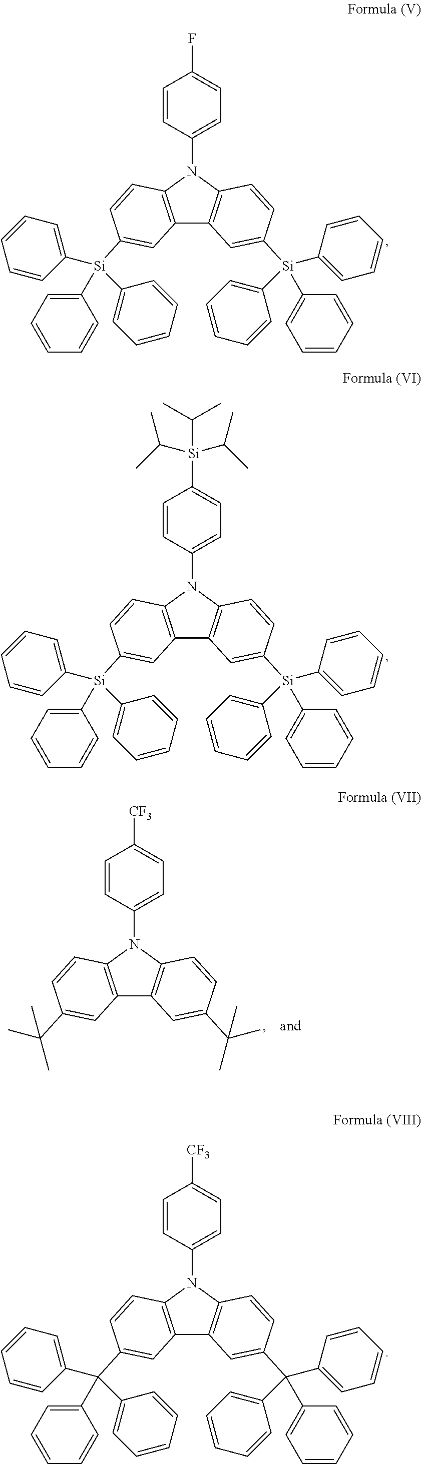

Generally, according to some embodiments of the present invention, the compounds of Formulae II to VI can be prepared by the following reaction scheme, i.e., via treatment of dibrominated or dichlorinated carbazole derivatives with n-BuLi at −78° C. to give dilithiated intermediates which are subsequently quenched with ClSi(Ph)₃ or

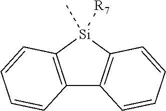

(where R₇ is phenyl or methyl) to give the corresponding compounds of Formulae II to VI.

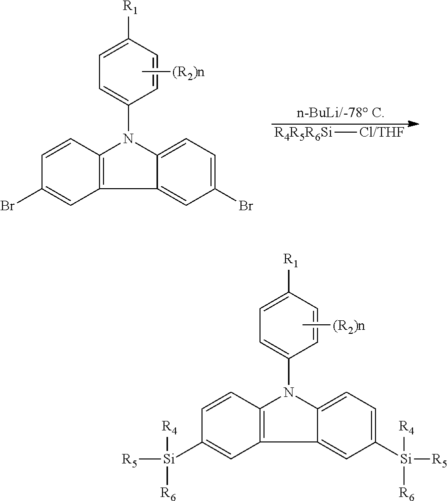

The synthetic methods suitable for the preparation of such compounds are described in detail in Wu et al., “Highly Efficient Organic Blue Electrophosphorescent Devices Based on 3,6-Bis(triphenylsilyl)carbazole as the Host Material,” Adv. Mater. 18: 1216-1220 (2006), which is hereby incorporated by reference in its entirety.

The carbazole-based compounds having suitable substituents such as the trialkyl or triaryl group of the present invention, particularly compounds of Formulae Ito VIII, have been previously found to be promising for large-scale light emitting diodes since they allow for solvent-processing techniques, such as spin-coating, (ink-jet) printing processes, high concentration demanding printing processes (roll to roll, flexography, etc), etc., while maintaining the other necessary properties for OLED devices.

The present invention is also directed to the use of the above compounds as host material in an emissive layer, where they function with an emissive material in an emissive layer in an organic light emitting device.

Suitable guest emissive (dopant) materials can be selected from those known in the art and hereafter developed including, without limitation, bis(2-phenylpyridine)iridium complexes, which exhibit a phosphorescent emission in the blue region of the spectrum. In specific embodiments, the guest exhibits a phosphorescent emission in the pure blue region of the spectrum.

If the emissive material is used as a dopant in a host layer comprising the compound of the present invention, it is generally used in an amount of at least 1% wt, specifically at least 3% wt, and more specifically at least 5% wt, with respect to the total weight of the host and the dopant. Further, it is generally used in an amount of at most 25% wt, specifically at most 20% wt, and more specifically at most 15% wt.

The present invention is also directed to an organic light emitting device (OLED) comprising an emissive layer, where the emissive layer comprises the host material described above. The OLED can also comprise an emissive material (where the light emitting material is present as a dopant), where the emissive material is adapted to luminesce when voltage is applied across the device.

The OLED generally comprises:

a glass substrate;

a generally transparent anode, such as an indium-tin oxide (ITO) anode;

a hole transporting layer (HTL);

an emissive layer (EML);

an electron transporting layer (ETL); and

a generally metallic cathode such as an Al layer.

For the hole conducting emissive layer, an exciton blocking layer, notably a hole blocking layer (HBL), may be present between the emissive layer and the electron transporting layer. For the electron conducting emissive layer, an exciton blocking layer, notably an electron blocking layer (EBL), may be present between the emissive layer and the hole transporting layer.

The emissive layer is formed with a host material comprising the compound of the present invention where the light emitting material exists as a guest. The emissive layer may further comprise an electron-transporting material selected from the group consisting of metal quinoxolates (e.g., aluminium quinolate (Alq₃), lithium quinolate (Liq)), oxadiazoles, and triazoles. A suitable example of the host material, without limitation, is 4,4′-N,N′-dicarbazole-biphenyl [“CBP”], which can be represented by the following formula:

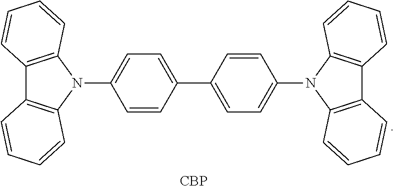

Optionally, the emissive layer may also contain a polarization molecule that is present as a dopant in the host material and has a dipole moment which generally affects the wavelength of the light emitted when the light emitting material used as a dopant luminesces.

The layer formed from the electron transporting material is used to transport electrons into the emissive layer comprising the light emitting material and the optional host material. The electron transporting material may be an electron-transporting matrix selected from the group consisting of metal quinoxolates (e.g., Alq₃ and Liq), oxadiazoles, and triazoles. A suitable example of the electron transporting material is, without limitation, tris-(8-hydroxyquinoline)aluminum of formula [“Alq₃”]:

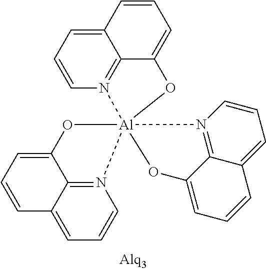

The layer formed from the hole transporting material is used to transport holes into the emissive layer comprising the light emitting material and the optional host material. A suitable example of the hole transporting material, without limitation, is 4,4′-bis[N-(1-naphthyl)-N-phenylamino]biphenyl [“α-NPD”] of the following formula:

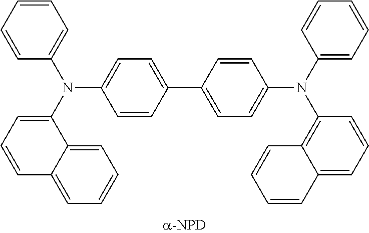

The use of the exciton blocking layer (“barrier layer”) to confine excitons within the luminescent layer (“luminescent zone”) is advantageous. For a hole-transporting host, the blocking layer may be placed between the emissive layer and the electron transport layer. A suitable example of the material for the barrier layer, without limitation, is 2,9-dimethyl-4,7-diphenyl-1,10-phenanthroline (also referred to as bathocuproine or “BCP”), which has the following formula:

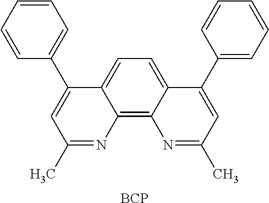

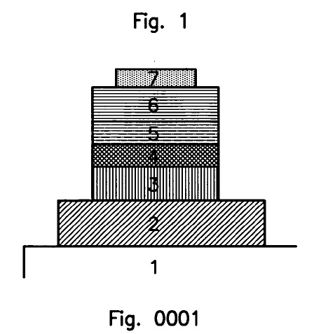

As depicted in FIG. 1, in some embodiments, the OLED according to the present invention has a multilayer structure where: 1 is a glass substrate; 2 is an ITO layer; 3 is an HTL layer comprising α-NPD; 4 is an EML comprising host material and the light emitting material as dopant in an amount of about 8% wt with respect to the total weight of the host plus dopant; 5 is an HBL comprising BCP; 6 is an ETL comprising Alga; and 7 is an Al layer cathode.

### EXAMPLES

Hereinafter, the present invention will be explained in detail with reference to examples and comparative examples. These examples, however, should not in any sense be interpreted as limiting the scope of the present invention. Further, units are expressed by weight unless otherwise described.

All raw materials were purchased from Aldrich (U.S.A.), AlfaAesar (U.S.A.) or TCI (Japan). Drum solvents (e.g., EtOAc, hexane, THF, acetonitrile, DMF, dichloromethane) were used herein and were purchased from Mallinckrodt (U.S.A.) and Tedia. Freshly distilled tetrahydrofurane was used as the solvent for metalation reactions.

All ¹H and ¹³C NMR spectra were recorded on a Bruker Avance III 400 NMR spectrometer at 400 MHz and 100 MHz, respectively, for solutions in CDCl₃. All in-process HPLC analyses were performed using a Hitachi Elite LaChrome machine. The reference wavelengths used were 254 nm and 220 nm. A CombiFlash Companion was used for the isolation and purification of the intermediates and final compounds. Thin layer chromatography was carried out using 2.5×7.5 cm Merck 60 F-254 plates, and the elution solvents were hexane and hexane/dichloromethane mixtures. All experiments were carried out under a nitrogen or argon atmosphere.

### Example 1

### Synthesis of 9-(4-(Triisopropylsilyl)phenyl)-3,6-bis(triphenylsilyl)-9H-carbazole (2PSCT) (Compound VI)

The synthesis of compound III was carried out as depicted in Scheme 1 below:

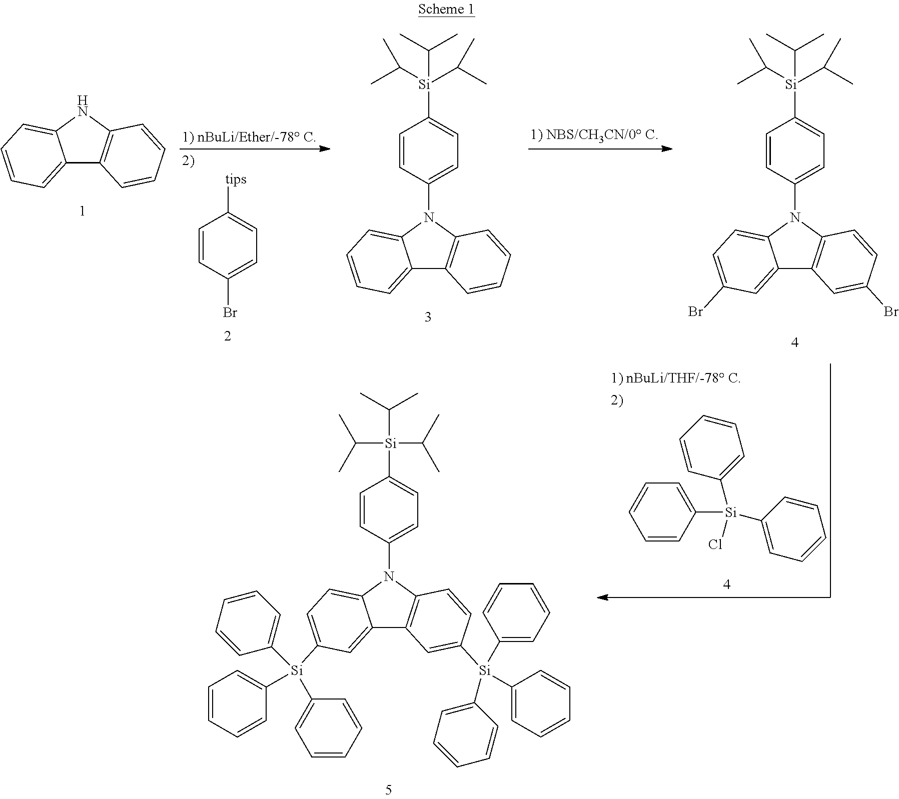

### Synthesis of 4-Bromophenyl)triisopropylsilane

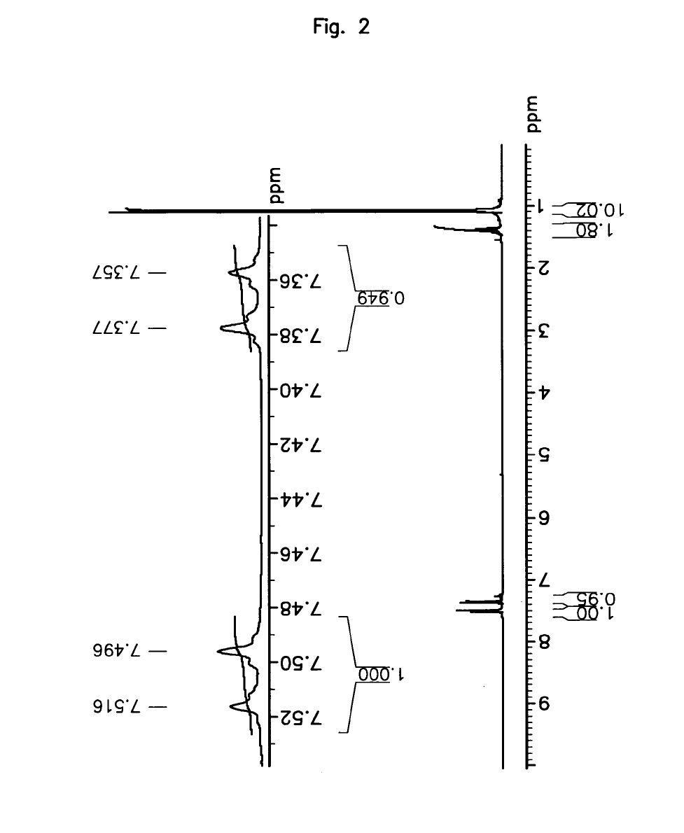

20.3 ml of n-BuLi (2.5 M/hexane, 50.8 mmol, 1.03 eq.) was added dropwise via a syringe to a stirred, cooled (−78° C.) solution of 1,4-dibromobenzene (12 g, 50.8 mmol) in ether. The rate of addition was controlled such that the temperature never exceeded −74° C. The reaction mixture was stirred for one hour at −78° C. and then for one hour at room temperature. No specific color changes were noticed during the addition of n-BuLi, nor during the course of the warming up of the contents. After two hours of stirring, the reaction mixture was brought back to −78° C. and to this an ether solution of triisopropyl triflate (13.7 ml, 1 eq.) was added dropwise via a syringe. The rate of addition was controlled such that the temperature never exceeded −74° C. The reaction mixture was quenched the next day using ice water and extracted with ethylacetate (3×75 ml). All organic fractions were combined, dried over MgSO₄, and concentrated under reduced pressure. A colorless oil was obtained, which was purified on CombiFlash (120 g column, hexane) to afford 6.5 g of clear oil. The purified product 2, i.e., 4-bromophenyl)triisopropylsilane, was analyzed by ¹H NMR spectroscopy (see FIG. 2).

### Synthesis of 9-(4-(Triisopropylsilyl)-phenyl)-9H-carbazole

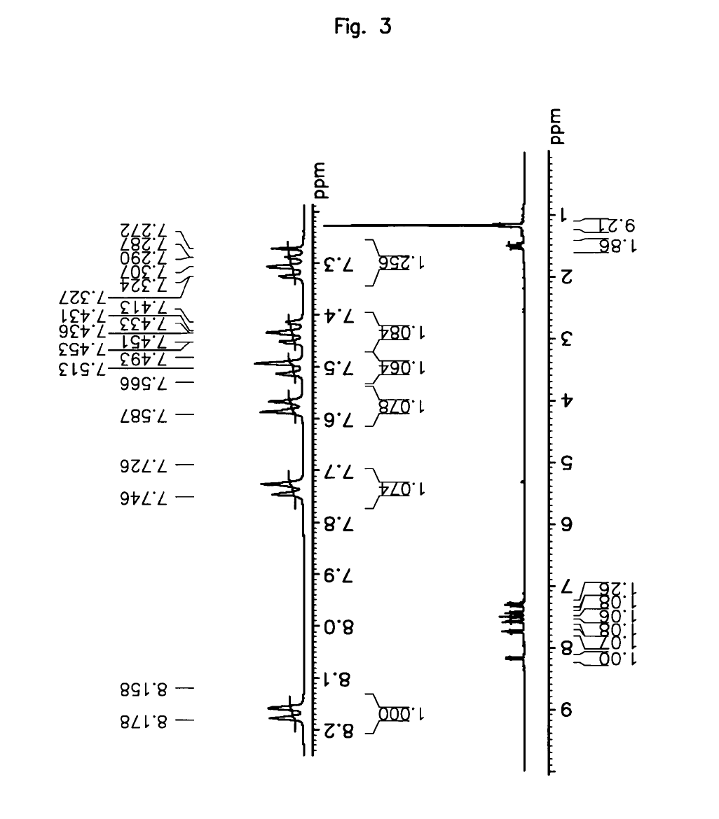

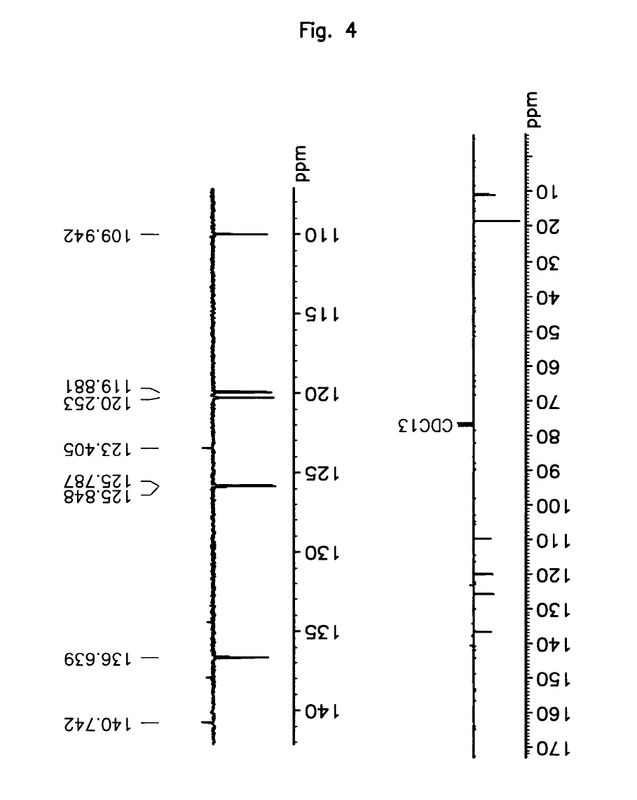

A three-necked 1 L round bottom flask was charged with a mixture of the carbazole 1 (2.62 g, 1 eq.), 4-bromophenyl)triisopropylsilane 2 (5.4 g, 17.2 mmol, 1.1 eq.), 18-crown-6 (0.621 g, 15 mol %), anhydrous K₂CO₃ (3.31 g, 1.53 eq.) and copper {(nano), 1.19 g, 1.2 eq.} in o-dichlorobenzene (35 ml). The dark colored mixture was stirred overnight at 178° C. The progress of the reaction was monitored by TLC (hexane). After the disappearance of the starting material, the contents of the reaction vessels were cooled and extracted with dichloromethane (3×100 ml). The combined organic layers were successively filtered with a cotton plug after every extraction. The resulting solution was dried over MgSO₄, filtered and concentrated on a rotary evaporator under high vacuum. A dark colored material was purified on CombiFlash (120 g column, hexane) to afford 3.69 g of white solid. The purified product 3, 9-(4-(triisopropylsilyl)phenyl)-9H-carbazole, was analyzed by ¹H NMR (see FIG. 3) and ¹³C NMR (see FIG. 4) spectroscopic methods.

### Synthesis of 3,6-dibromo-9-(4-(triisopropylsilyl)-phenyl)-9H-carbazole

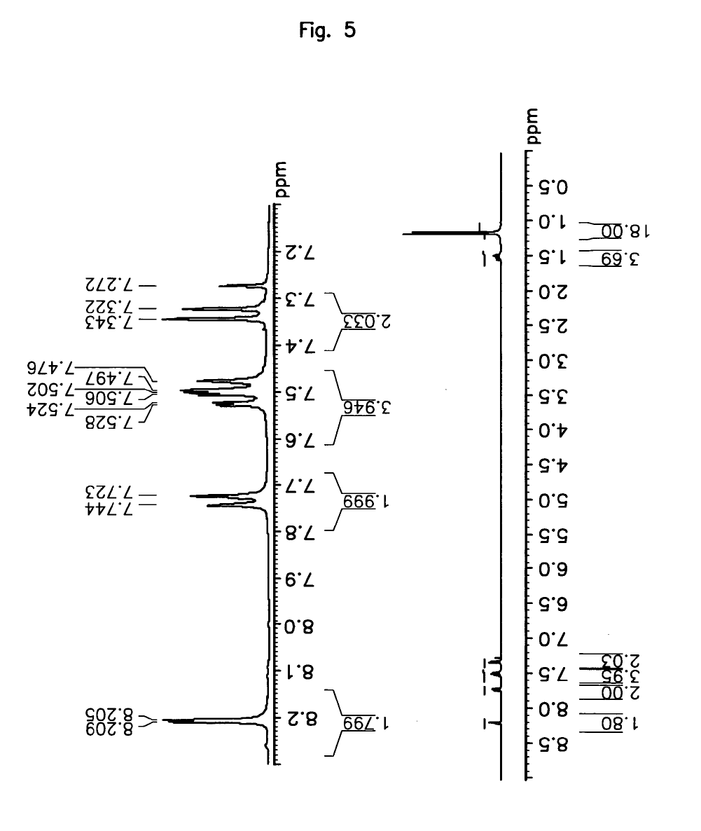

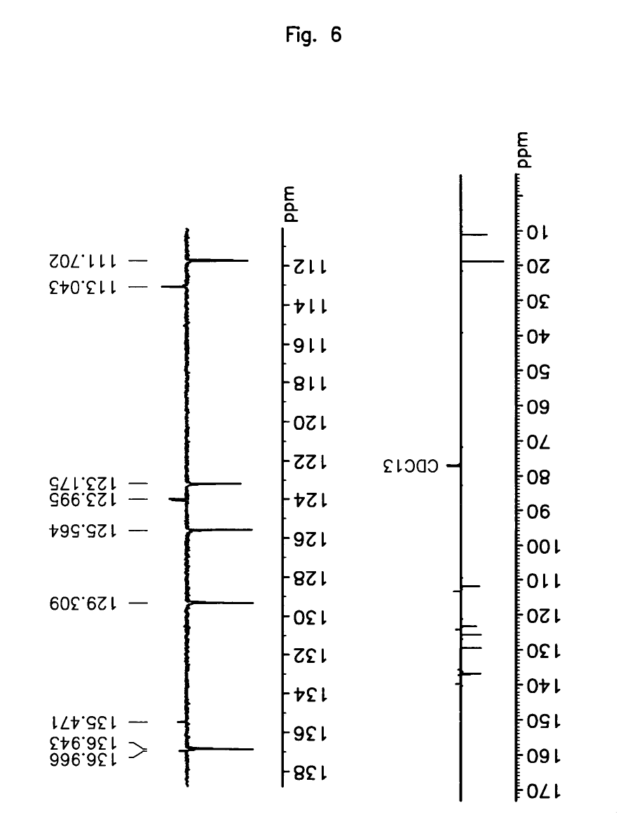

3.61 g of N-bromosuccinimide (2.2 eq.) was added slowly to a stirred, cooled (0° C.) solution of 3 (3.69 g, 9.23 mmol) in acetonitrile (80 ml, HPLC grade). The rate of addition was controlled such that the temperature never exceeded 0° C. The white suspension was stirred overnight. The progress of the reaction was monitored by TLC (hexane). After the completion of the reaction, the contents of the reaction vessels were cooled (0° C.), filtered and washed with cold acetonitrile (2×30 ml) and hexane (2×50 ml), and dried under vacuum to constant weight to yield 4.55 g of fluffy white solid. The dried product 4,3,6-dibromo-9-(4-(triisopropylsilyl)phenyl)-9H-carbazole was analyzed by ¹H NMR (see FIG. 5) and ¹³C NMR (see FIG. 6) spectroscopic methods.

### Synthesis of 9-(4-(Triisopropylsilyl)-phenyl)-3,6-bis(triphenylsilyl)-9H-carbazole (2PSCT)

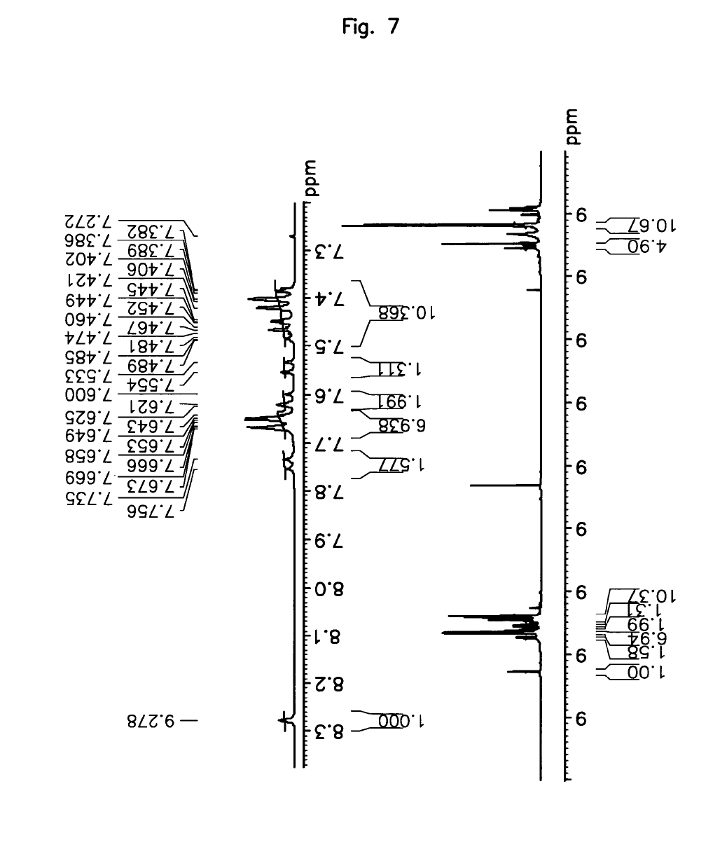

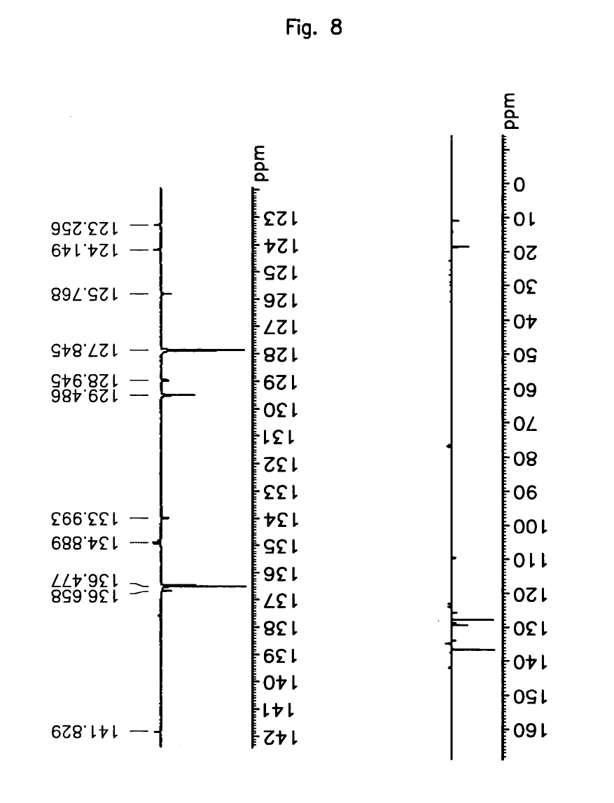

4.9 ml of n-BuLi (2.5 M/hexane, 12.09 mmol, 1.5 eq. per each bromine) was added dropwise via a syringe to a stirred, cooled (−78° C.) solution of 4 (12 g, 50.8 mmol) in THF. The rate of addition was controlled such that the temperature never exceeded −74° C. The reaction mixture was stirred for 40 minutes at −78° C. The color of the solution changed from colorless to yellow during the addition of n-BuLi. After a predetermined time, a solution of freshly recrystallized (hexane/ether) triphenylsilylchloride (3.57 g, 3 eq.) in THF was added dropwise via a syringe. The rate of addition was controlled such that the temperature never exceeded −74° C. The reaction mixture was quenched the next day using ice water and extracted with ethylacetate (3×75 ml). The combined organic fractions were dried over MgSO₄ and concentrated under reduced pressure. After concentration, the crude product was purified on CombiFlash (330 g column, hexane/dichloromethane as eluent) to give 2.58 g of 9-(4-(triisopropylsilyl)phenyl)-3,6-bis(triphenylsilyl)-9H-carbazole 5 as a white crystalline solid. The purified product 5 was analyzed by ¹H NMR (see FIG. 7) and ¹³C NMR (see FIG. 8) spectroscopic methods.

It will be apparent to those skilled in the art that various modifications and variations can be made to the present invention without departing from the spirit and scope of the invention. Thus, it is intended that the present disclosure covers the modifications and variations of this invention, provided they come within the scope of the appended claims and their equivalents.

1. A compound of Formula I: 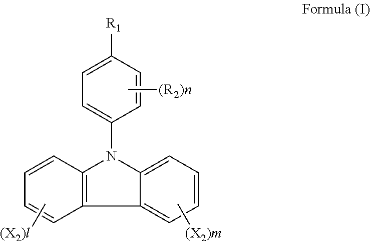
wherein:
R₁ is fluorinated alkyl, halogen or —SiR₄R₅R₆ where each of R₄, R₅ and R₆ is an alkyl group;
R₂, X₁ and X₂ are non-conjugate substituents, the same or different at each occurrence and selected from the group consisting of:
trityl
halogen;
nitro;
cyano;
—COOR₃;
—SiR₄R₅R₆; and
straight-chain or branched or cyclic alkyl or alkoxy or dialkylamino group having from 1 to 20 carbon atoms wherein one or more nonadjacent —CH₂— groups may be replaced by —O—, —S—, —NR₂—, —CO—, —CONR₇ or —COO— and wherein at least one hydrogen atoms may be replaced by halogen;
wherein R₃, R₄, R₅, R₆, R₇, and R₈, are the same or different at each occurrence and independently selected from the group consisting of —H, halogen, nitro, cyano, straight or branched C₁₋₂₀-alkyl, C₃₋₂₀-cyclic alkyl, straight or branched C₁₋₂₀-alkoxy, C₁₋₂₀-dialkylamino, C₄₋₁₄-aryl, C₄₋₁₄-aryloxy, and C₄₋₁₄-heteroaryl, which may be substituted by one or more non aromatic radicals, wherein a plurality of R₁, R₂, R₄, R₅, R₆, X₁ and X₂ may in turn together form a mono- or polycyclic ring, optionally aromatic; and
l, m, and n are the same or different at each occurrence and represents an integer from 0 to 4.

2. The compound of claim 1, wherein R₁ is trialkylsilyl.

3. The compound of claim 2, wherein R₁ is Si(isopropyl)₃.

4. The compound of claim 1, wherein each of X₁ and X₂ is a triarylsilyl group.

5. The compound of claim 4, wherein X₁=X₂=—Si(Ph)₃.

6. The compound of claim 1, wherein 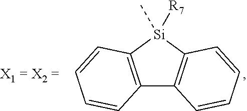
where R₇ is phenyl, isopropyl or methyl.

7. The compound of claim 6, represented by Formula II:

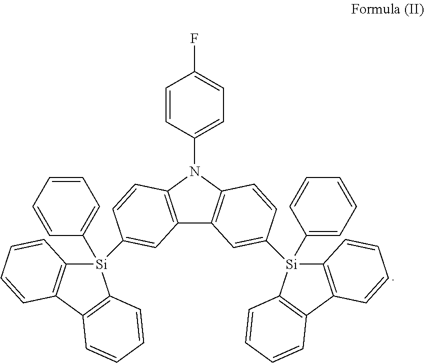

8. The compound of claim 6, represented by Formula III:

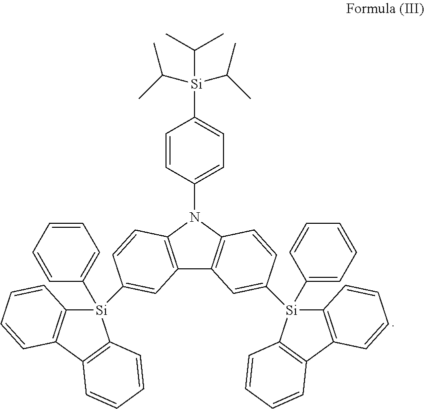

9. The compound of claim 6, represented by Formula IV: 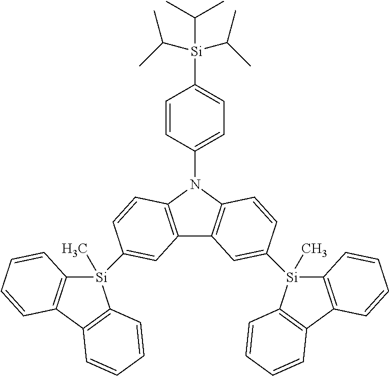
Formula (IV), or by the same formula but where the methyl groups are replaced with isopropyl groups.

10. The compound of claim 5, represented by Formula V:

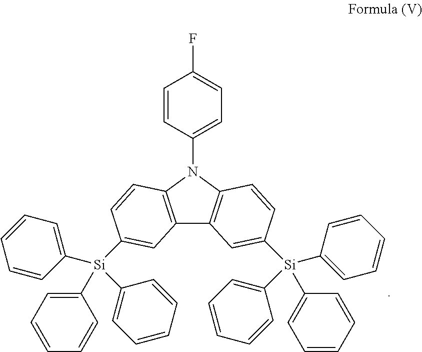

11. The compound of claim 5, represented by Formula VI:

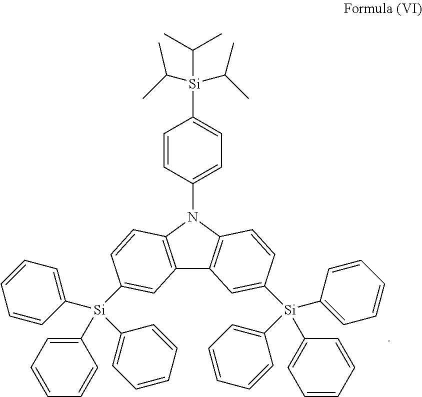

12. The compound of claim 1, represented by Formula VII:

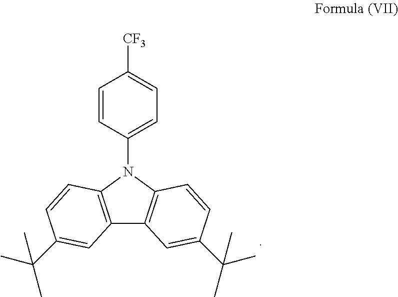

13. The compound of claim 1, represented by Formula VIII:

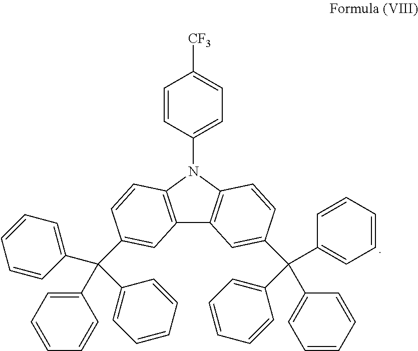

14. (canceled)

15. An organic light emitting device (OLED) comprising an emissive layer (EML), where the emissive layer comprises a host material which is the compound of claim 1.

16. The organic light emitting device (OLED) of claim 15, which comprises:
a glass substrate;
an anode;
a hole transporting layer (HTL);
the emissive layer (EML);
an electron transporting layer (ETL); and
a cathode.

17. The organic light emitting device (OLED) of claim 16, wherein the anode is transparent and the cathode is metallic.

18. The organic light emitting device (OLED) of claim 16, wherein the host material is a compound having a formula selected from the group consisting of: 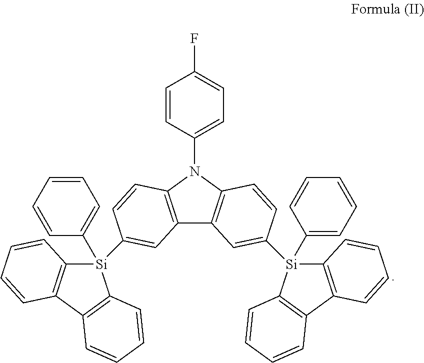 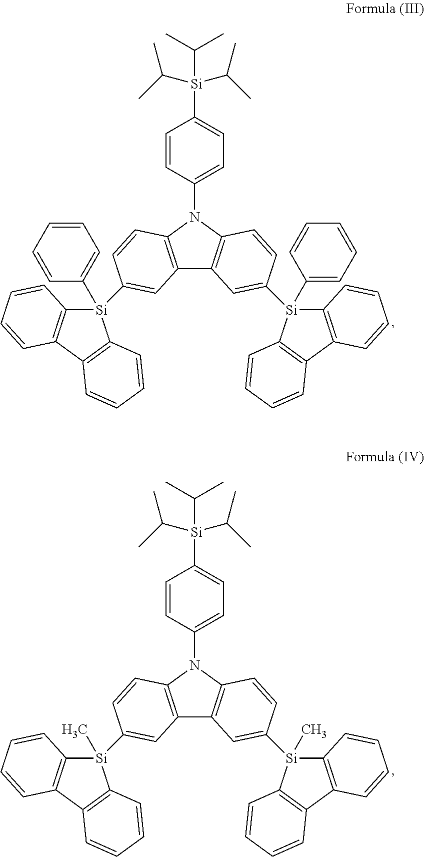
the same formula as formula (IV) but where the methyl groups are replaced with isopropyl groups,

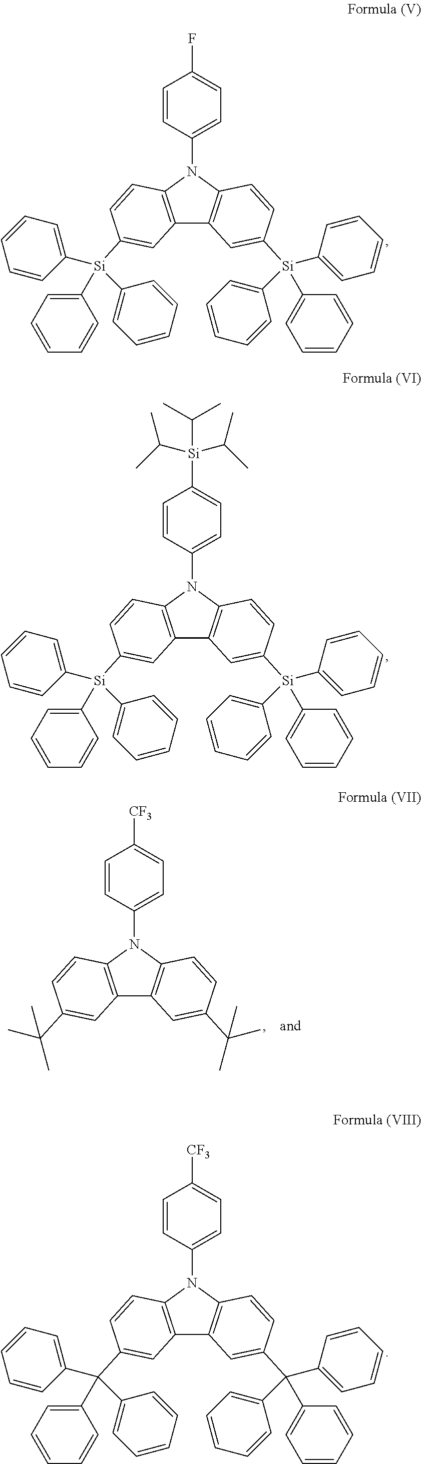

19. A method for emitting blue light, which comprises using the organic light emitting device (OLED) of claim 16.

20. A method for emitting blue light, which comprises using the organic light emitting device (OLED) of claim 17.

21. A method for emitting blue light, which comprises using the organic light emitting device (OLED) of claim 18.
